(19) United States
(12) Patent Application Publication
(10) Pub. No.: US 2019/0104644 A1
(43) Pub. Date: Apr. 4, 2019

(54) ELECTRONIC DEVICE

(71) Applicant: FUJITSU LIMITED, Kawasaki-shi (JP)

(72) Inventors: HIROMU SHOJI, Kawasaki (JP); Katsuki Sawada, Fuchu (JP)

(73) Assignee: FUJITSU LIMITED, Kawasaki-shi (JP)

(21) Appl. No.: 16/139,321

(22) Filed: Sep. 24, 2018

(30) Foreign Application Priority Data
Sep. 29, 2017 (JP) 2017-191672

(51) Int. Cl. H05K 7/20; H05K 5/06; H04B 7/26; H04B 1/40; H04W 88/08

(52) U.S. Cl. CPC H05K 7/20409; H05K 5/069; H04W 88/08; H04B 1/40; H04B 7/26

(57) ABSTRACT

An electronic device includes a casing, circuit boards disposed in the casing, heat-producing components mounted over the circuit boards, outer fins protruding toward the outside of the casing, and inner fins coupled to an inner surface of the casing, the inner fins being disposed in a space adjacent to areas in which the circuit boards are not mounted in the casing, wherein heat of the heat-producing components absorbed by the inner fins is dissipated to the outside of the casing through the outer fins.

### CROSS-REFERENCE TO RELATED APPLICATION

This application is based upon and claims the benefit of priority of the prior Japanese Patent Application No. 2017-191672, filed on Sep. 29, 2017, the entire contents of which are incorporated herein by reference.

### FIELD

The embodiments discussed herein are related to an electronic device having a structure for cooling heat-producing components.

### BACKGROUND

The demand for size-reduced electronic devices has been increasing, and also for wireless communication base stations for wireless terminals such as mobile phones, the demand for size-reduced electronic devices has been increasing. Such an electronic device used as a base station is installed outdoors and attached to the rooftop of a building structure or a utility pole and its installation cost is determined based on the occupied volume of the electronic device. Consequently, more compact electronic devices are desired. With the reduction in size of the electronic devices in base stations, electronic components such as a power supply device and a power amplifier in an electronic device are becoming denser.

FIG. 1A is an external view of an electronic device 10 according to a comparative technique used as a wireless base station. A casing 9 of the electronic device 10 includes a first end face plate 1, a second end face plate 2, and a rectangular case 3 that is sandwiched between the first end face plate 1 and the second end face plate 2. The first end face plate 1 has a plurality of fins 11 that protrude outwardly. The first end face plate 1 and the first fins 11 constitute a first heat sink 21. The second end face plate 2 has a plurality of fins 12 that protrude outwardly. The second end face plate 2 and the second fins 12 constitute a second heat sink 22. The case 3 has third fins 13 that protrude from wall surfaces of the electronic device 10 in a left-right direction.

FIG. 1B is an exploded view of the electronic device 10 illustrated in FIG. 1A, the view illustrating an internal structure of the casing 9. The first end face plate 1 has an outer surface that has the first fins 11 that protrude from the outer surface and an inner surface that is flat. To the flat surface of the first end face plate 1, a first circuit board 41 on which first heat-producing components 31 such as power amplifiers are mounted is attached, for example, with a screw fastened into a boss (not illustrated). The area of the first circuit board 41 is smaller than the area of the flat surface of the first end face plate 1. The flat surface of the first end face plate 1 has areas E and F on which the first circuit board 41 is not mounted.

Similarly, the second end face plate 2 has an outer surface that has the second fins 12 that protrude from the outer surface and an inner surface that is flat. To the flat surface of the second end face plate 2, a second circuit board 42 on which second heat-producing components 32 such as power amplifiers are mounted is attached, for example, with a screw fastened into a boss (not illustrated). The area of the second circuit board 42 is substantially the same as the area of the flat surface of the second end face plate 2. Most of the flat surface of the second end face plate 2 is covered with the second circuit board 42. On one of the first circuit board 41 and the second circuit board 42, digital circuit components are mounted, and on the other one, analog circuit components are mounted.

The case 3 has a first flange section 51 that is joined to an outer edge section of the first end face plate 1, a second flange section 52 that is joined to an outer edge section of the second end face plate 2, and a frame 53 that connects the first flange section 51 and the second flange section 52. From left and right outer surfaces of the frame 53 of the case 3, the above-described third fins 13 protrude.

The electronic device that is used as a base station is installed outdoors, and thus the casing 9 has a waterproof structure so as to protect various devices inside the electronic device from wind and rain. For this purpose, the first flange section 51 that is joined to the outer edge section of the first end face plate 1 and the second flange section 52 that is joined to the outer edge section of the second end face plate 2 have sealing members 4 that reduce water entering the inside of the electronic device 10. Inside the case 3, a transmit-receive switch 5 that has a circuit for switching between transmission and reception is disposed.

In a case where the electronic device 10 is an outdoor base station, among electronic components accommodated inside the case 3, components that produce a considerable amount of heat are the heat-producing components 31 and 32 such as power amplifiers. In order to reduce the size of an outdoor base station, in some cases, the heat-producing components 31 and 32 are mounted on different two circuit boards to dissipate the heat from the heat-producing components 31 and 32. In the electronic device 10 according to the comparative technique, the heat-producing components 31 and the heat-producing components 32 are separately mounted and the first circuit board 41 on which the heat-producing components 31 are mounted is attached to the first end face plate 1, and the second circuit board 42 on which the heat-producing components 32 are mounted is attached to the second end face plate 2.

With this structure, in the electronic device 10 according to the comparative technique, the heat generated by the heat-producing components 31 is mainly dissipated from the first heat sink 21, which includes the first end face plate 1 and the first fins 11. Similarly, the heat generated by the heat-producing components 32 is mainly dissipated from the second heat sink 22, which includes the second end face plate 2 and the second fins 12.

FIG. 2 illustrates the first heat sink 21 in FIG. 1B viewed from the inside of the electronic device in which the first circuit board 41, on which the first heat-producing components 31 are mounted, is attached to the first end face plate 1 of the first heat sink 21. The first circuit board 41 is fixed to a boss that protrudes from the first end face plate 1 with a screw or the like; however, the screw is omitted in FIG. 2. The first circuit board 41 is attached to a part of the first end face plate 1. The flat surface of the first end face plate 1 has the above-described areas E and F in which the first circuit board 41 is not mounted.

FIG. 3A illustrates the second heat sink 22 in FIG. 1B viewed from the inside of the electronic device in which the second circuit board 42, on which the second heat-producing components 32 are mounted, is attached to the second end face plate 2 of the second heat sink 22. FIG. 3B illustrates the second end face plate 2 to which the second circuit board 42 illustrated in FIG. 3A is attached, the view from the arrow A direction. The second circuit board 42 is fixed to a boss that protrudes from the second end face plate 2 with a screw or the like; however, the screw is omitted in FIG. 3A and FIG. 3B. The second circuit board 42 is attached to substantially the entire surface of the second end face plate 2.

In the electronic device according to the comparative technique, however, due to the high-density electronic components such as power supply device and power amplifiers, the radiating fins installed outside the casing fail to sufficiently radiate the heat, causing temperature rise in the electronic device. In order to increase the radiation performance, a heat pipe may be mounted inside the casing of the electronic device; however, this increases the cost of the electronic device, and even if the temperature of the components may be lowered, local heating may not be suppressed.

The followings are reference documents.

[Document 1] Japanese Laid-open Patent publication No. 2011-181880 and

### [Document 2] Japanese Laid-Open Patent Publication No. 09-322223.

### SUMMARY

According to an aspect of the invention, an electronic device includes a casing, circuit boards disposed in the casing, heat-producing components mounted over the circuit boards, outer fins protruding toward the outside of the casing, and inner fins coupled to an inner surface of the casing, the inner fins being disposed in a space adjacent to areas in which the circuit boards are not mounted in the casing, wherein heat of the heat-producing components absorbed by the inner fins is dissipated to the outside of the casing through the outer fins.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a perspective view illustrating an external appearance of an electronic device according to a comparative technique used as a wireless base station;

FIG. 1B is an exploded perspective view of the electronic device illustrated in FIG. 1A;

FIG. 2 illustrates a first end face plate illustrated in FIG. 1B to which a first circuit board is attached, the view from the inside of the electronic device;

FIG. 3A is a perspective view illustrating a second heat sink in FIG. 1B to which a second circuit board is attached;

FIG. 3B illustrates a second end face plate to which the second circuit board illustrated in FIG. 3A is attached, the view from the arrow A direction;

FIG. 4A is an exploded perspective view illustrating an electronic device according to an embodiment;

FIG. 4B illustrates a first end face plate in FIG. 4A to which a first circuit board is attached, the view from the inside of the electronic device;

FIG. 5 is a side view of an electronic device including a partial cross section for describing a function of inner fins in a first heat sink inside an electronic device according to an embodiment;

FIG. 6A is a perspective view illustrating the distribution of temperature on a surface of a casing during operation of an electronic device according to the comparative technique;

FIG. 6B is a perspective view illustrating the distribution of temperature on a surface of a casing during operation of an electronic device according to an embodiment;

FIGS. 7A to 7D illustrate steps of manufacturing a first heat sink in an electronic device according to an embodiment;

FIG. 7A is a perspective view of a first heat sink having fins on both sides formed by cutting an aluminum plate;

FIG. 7B is a perspective view of the first heat sink illustrated in FIG. 7A, the first heat sink having grooves on a surface that is exposed to the outside air, the grooves formed by cutting the surface;

FIG. 7C is a perspective view illustrating the first heat sink in FIG. 7B, the first heat sink having inner fines that protrude from an inner side of the first heat sink formed by cutting with requisite portions of the inner fines remained, and to which a first circuit board is being attached;

FIG. 7D is a perspective view of the first heat sink in FIG. 7C having the first circuit board that has been attached on the inner side of the first heat sink;

FIG. 8 illustrates an embodiment in which inner fins are formed in an area in which the first circuit board is not mounted in the first end face plate to which the first circuit board has been attached, the view from the inside of the electronic device;

FIG. 9A is a perspective view illustrating an embodiment in which separately formed inner fins are fitted into a recessed portion in a first end face plate to make a first heat sink; and

FIG. 9B is a perspective view illustrating still another embodiment in which separately formed inner fins are attached to a recessed portion in a first end face plate with a thermally conductive sheet or thermally conductive adhesive tape therebetween to make a first heat sink.

### DESCRIPTION OF EMBODIMENTS

Hereinafter, specific embodiments will be described in detail with reference to the attached drawings. In the embodiments described below, the same reference numerals are given to elements the same as or similar to those of the electronic device according to the comparative technique, and the scale of the drawings are appropriately changed to facilitate understanding.

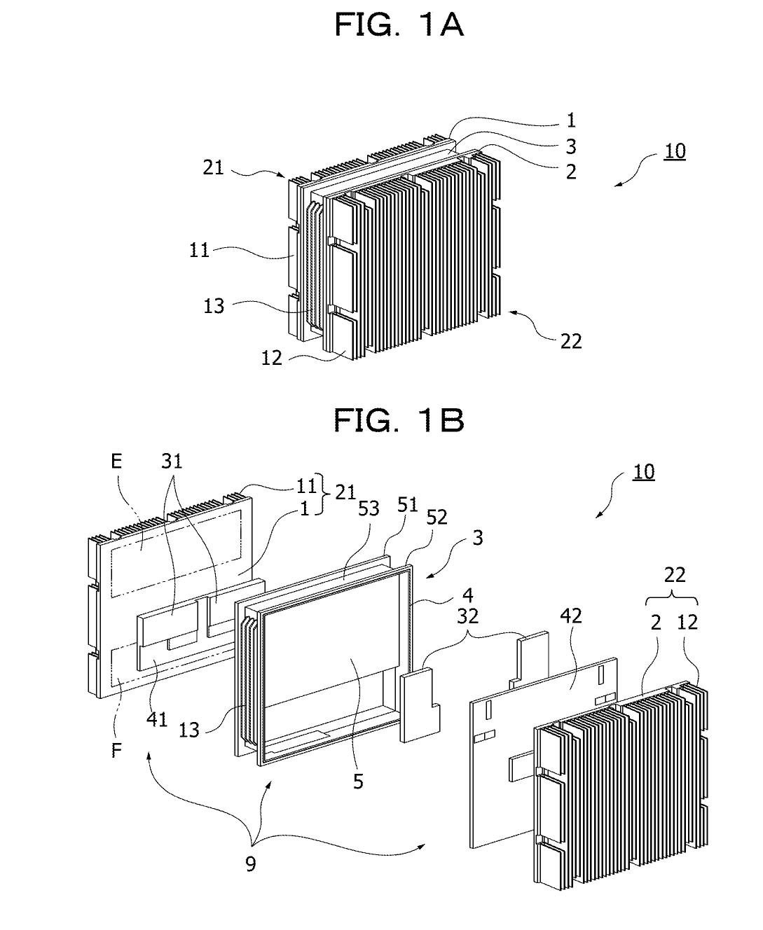

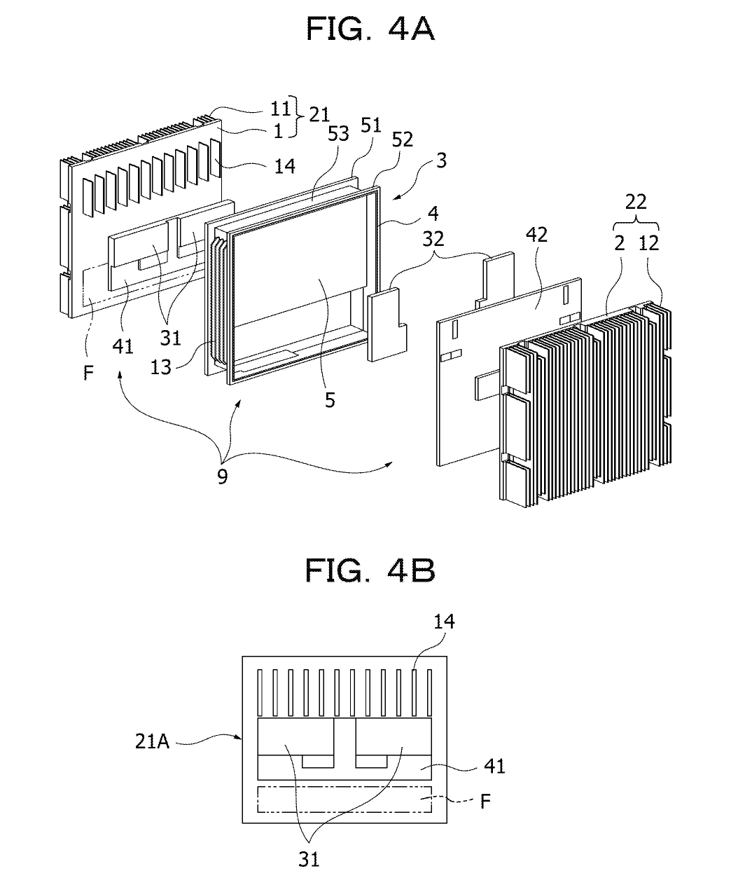

FIG. 4A is an exploded perspective view of an electronic device 20 according to an embodiment, the view illustrating an internal structure of a casing 9. FIG. 4B illustrates a first end face plate 1 in FIG. 4A to which a first circuit board 41 is attached, the view from the inside of the electronic device 20. The casing 9 of the electronic device 20 includes the first end face plate 1, a second end face plate 2, and a rectangular case 3 that is sandwiched between the first end face plate 1 and the second end face plate 2. The appearance shape of the assembled components is similar to that of the electronic device 10 according to the comparative technique illustrated in FIG. 1A. The electronic device 20 is similar to the electronic device 10 according to the comparative technique illustrated in FIG. 1B in that the first end face plate 1 has a plurality of first fins 11 on an outer side, the second end face plate 2 has a plurality of second fins 12 on an outer side, and the case 3 has third fins 13 that protrude outwardly.

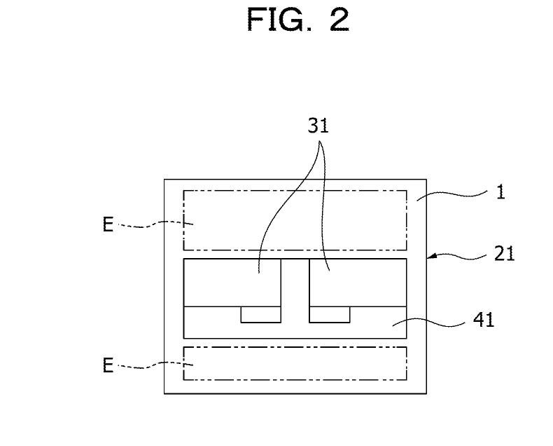

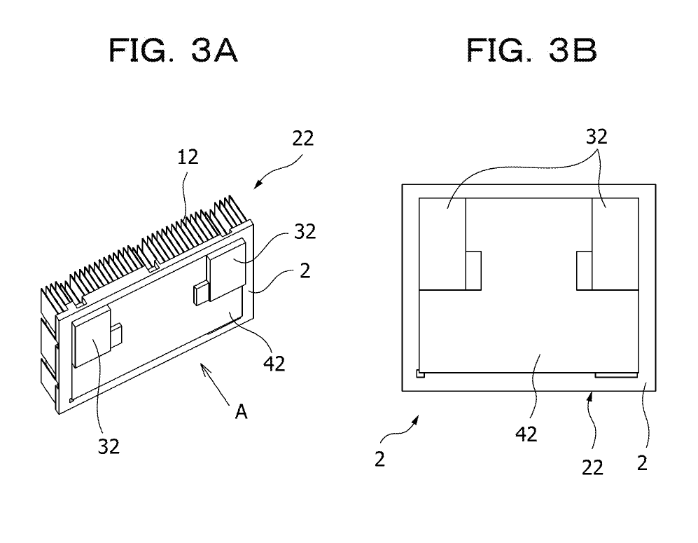

The structure of the electronic device 20 in this embodiment differs from that of the electronic device 10 according to the comparative technique described in FIG. 1A and FIG. 2 only in the structure of a first heat sink 21. Accordingly, in the description of the structure of the electronic device 20 after FIGS. 4A and 4B, the same reference numerals are given to components similar to those in the electronic device 10 according to the comparative technique, their descriptions will be omitted, and only different structures will be described.

The electronic device 10 according to the comparative technique has the first heat sink 21 consisting of the first end face plate 1 and the first fins 11 and as illustrated in FIG. 2, the plane surface of the first end face plate 1 includes the areas E and F in which the first circuit board 41 is not mounted. The electronic device 20 according to the embodiment differs from the electronic device 10 in that a plurality of inner fins 14 are formed in the area E in which the first circuit board 41 is not mounted in the plane surface of the first end face plate 1. The area F in which the first circuit board 41 is not mounted in the plane surface of the first end face plate 1 is the same as that in the electronic device 10.

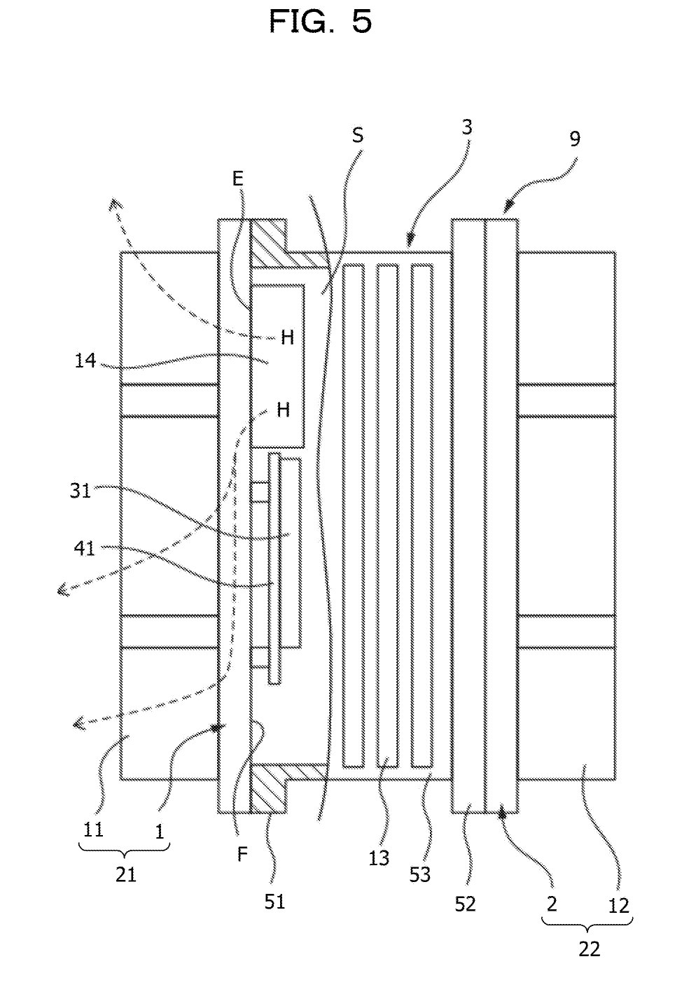

As illustrated in FIG. 5, the inner fins 14 are formed in a space S adjacent to the area E, in which the first circuit board 41 on which the heat-producing components 31 are mounted is not mounted, in the case 3 and the inner fins 14 do not interfere with other components. Although the number of the inner fins 14 in FIGS. 4A and 4B is reduced in order to facilitate the understanding of the description, the number of the inner fins 14 may be the same as the number of the first fins 11 formed on the outer side of the first end face plate 1.

With this structure, the inner fins 14 formed in the space S in the case 3 absorb the heat H from the first heat-producing components 31, which are mounted on the first circuit board 41, and dissipate the heat H to the outside through the first end face plate 1 and the first fins 11 indicated by the broken lines. With this heat dissipation, the internal temperature of the space S in the case 3 is decreased as compared with the temperature in the structure that has no inner fins 14.

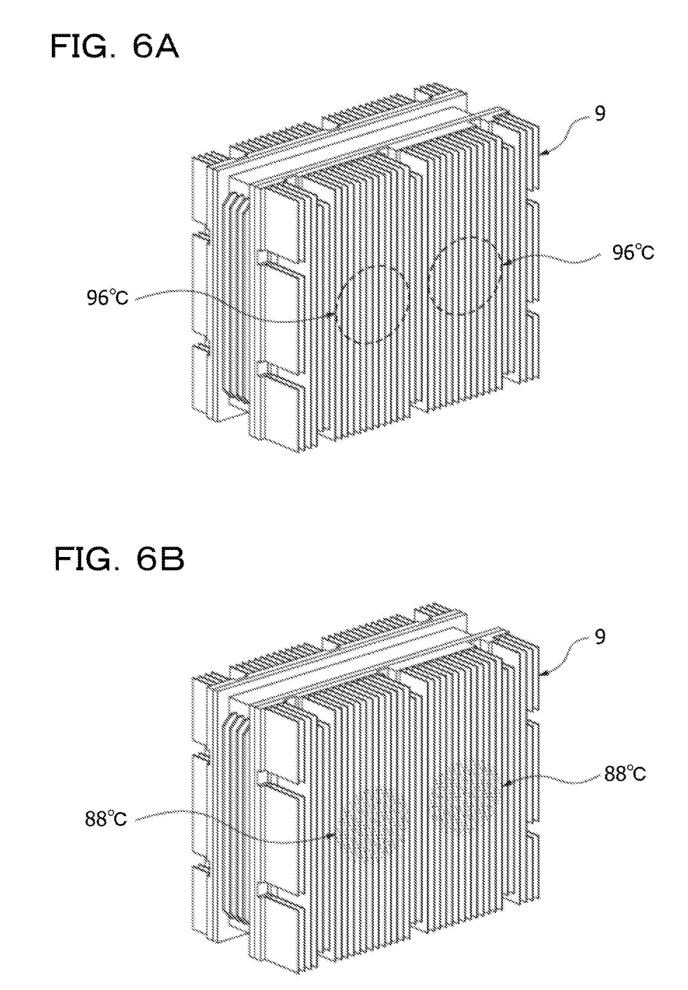

FIG. 6A illustrates the distribution of temperature on the surface of the casing 9 during operation of the electronic device 10 according to the comparative technique. Some portions in the surface of the casing 9 had a maximum temperature of 96° C. On the other hand, in the electronic device 20 that has the inner fins 14 described in FIGS. 4A and 4B, the maximum temperature of the surface of the casing 9 was reduced to 88° C., and thus the structure was effective to reduce the temperature of the casing 9 of the electronic device 20.

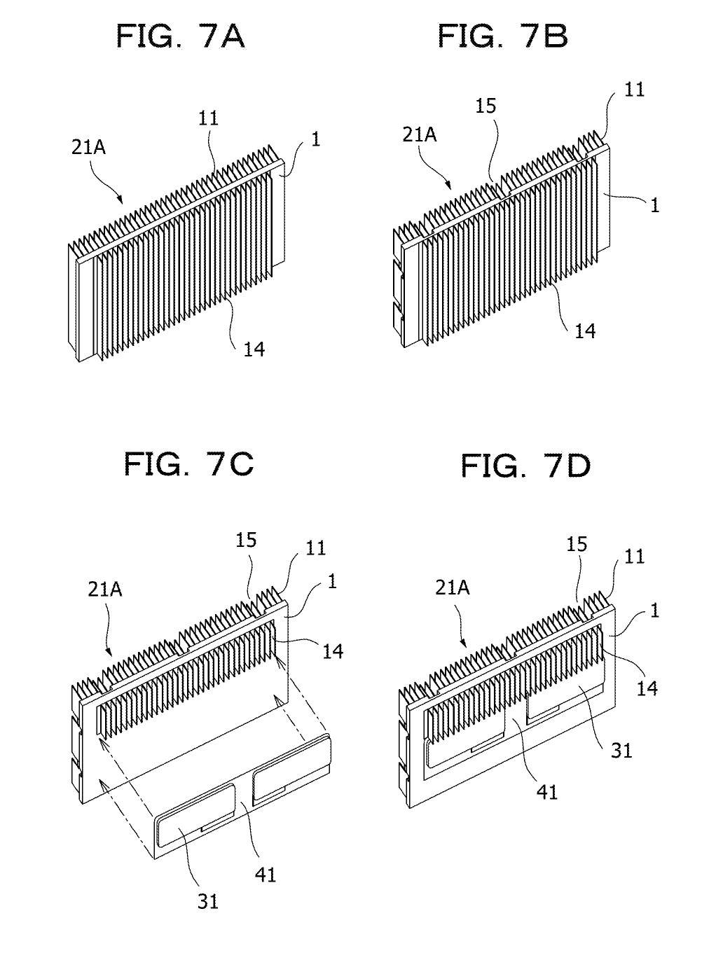

The first heat sink 21A in the electronic device 20 according to the embodiment includes the first end face plate 1, the first fins 11, and the inner fins 14. In the embodiment illustrated in FIGS. 4A and 4B, the inner fins 14 are integrally formed to the first end face plate 1. A method of manufacturing the first heat sink 21A will be described with reference to FIGS. 7A to 7D.

FIGS. 7A to 7D illustrate steps of manufacturing the first heat sink 21A in the electronic device 20. As illustrated in FIG. 7A, a rectangular parallelepiped aluminum plate is cut to form the first end face plate 1 and fins (the first fins 11 and the inner fins 14) on both sides of the first end face plate 1. Then, as illustrated in FIG. 7B, outer peripheral portions of the first fins 11 are partially cut off to form grooves 15 such that the first fins 11 are exposed more to the outside air.

After that, as illustrated in FIG. 7C, a part of the inner fins 14 is cut off such that the first circuit board 41 on which the first heat-producing components 31 are mounted may be mounted on the cut portion. To the portion from which the inner fins 14 have been removed, the first circuit board 41, on which the first heat-producing components 31 are mounted, is mounted. FIG. 7D illustrates the first heat sink 21A having the first circuit board 41, which has the first heat-producing components 31, mounted on the portion from which the inner fins 14 illustrated in FIG. 7C have been removed.

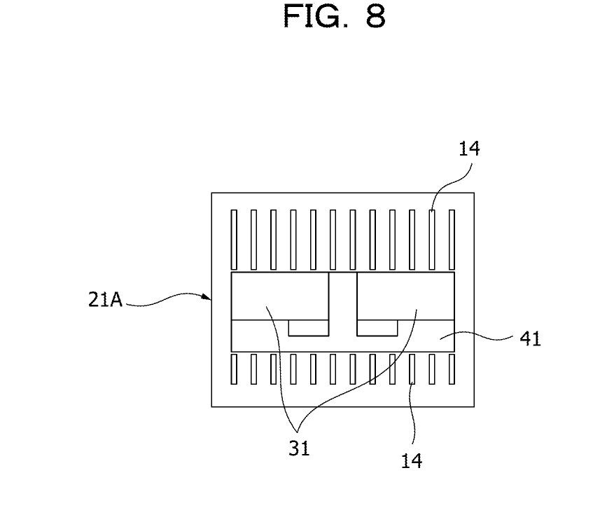

In the above-described embodiment, the inner fins 14 are formed only in the area E in which the first circuit board 41 is not mounted in the flat surface of the first end face plate 1; however, the inner fins 14 may also be formed in the area F in which the first circuit board 41 is not mounted as illustrated in FIG. 8.

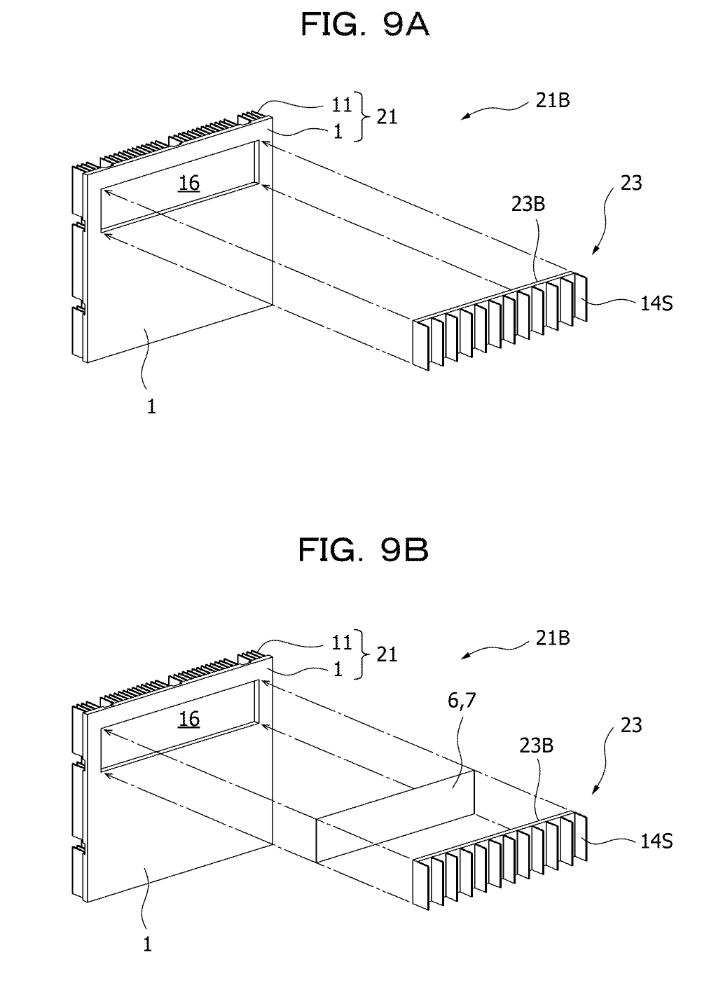

In the above-described embodiments, the inner fins 14 and the flat surface of the first end face plate 1 are integrally formed. Alternatively, in an embodiment, the inner fins 14 may be formed separately from the first end face plate 1 and the inner fins 14 may be attached to the first end face plate 1 in a state in which the thermal conductivity is ensured. In such a case, as illustrated in FIG. 9A, a recessed portion 16 is formed in an area in which the first circuit board 41 is not mounted in the first end face plate 1. Furthermore, a third heat sink 23 that has a base plate 23B of a shape similar to that of the recessed portion 16 and has a plurality of inner fins 14A that protrude from the base plate 23B is separately prepared. The base plate 23B of the third heat sink 23 is fit into the recessed portion 16 in the first end face plate 1 to form a first heat sink 21B. The shape of the first heat sink 21B that has the third heat sink 23 that has been fitted into the first end face plate 1 is similar to the shape of the first heat sink 21 that has the integrally formed inner fins 14.

As a modification of the embodiment illustrated in FIG. 9A, an embodiment illustrated in FIG. 9B may be made. In this modified embodiment, as illustrated in FIG. 9B, a thermally conductive sheet 6 or a thermally conductive adhesive tape 7 for ensuring heat conductivity may be disposed between the recessed portion 16 and the third heat sink 23 to form the first heat sink 21B. The thermally conductive sheet 6 or the thermally conductive adhesive tape 7 efficiently conducts the heat absorbed by the third heat sink 23 to the first end face plate 1.

In the above-described embodiments, as example electronic devices, the electronic devices that are used as base stations installed outdoors have been described; however, the installation location of the electronic devices is not limited to the outdoors. That is, any electronic device may be used as an electronic device according to an embodiment of the application as long as an electronic device has outer fins on the casing 9, a space inside the casing 9, and a structure for conducting heat from inner fins in the space to the outer fins.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a casing;
circuit boards disposed in the casing;
heat-producing components mounted over the circuit boards;
outer fins protruding toward the outside of the casing; and
inner fins coupled to an inner surface of the casing, the inner fins being disposed in a space adjacent to areas in which the circuit boards are not mounted in the casing,
wherein heat of the heat-producing components absorbed by the inner fins is dissipated to the outside of the casing through the outer fins.

2. The electronic device according to claim 1,
wherein the casing includes a cylindrical case and first and second end face plates that seal both ends of the cylindrical case, and
the inner fins protrude from at least one of inner surface sides of the first end face plate and the second end face plate such that the inner fins are integrally formed to the first end face plate or the second end face plate.

3. The electronic device according to claim 2,
wherein the outer fins are formed on one sides of the first end face plate and the second end face plate respectively, and
each of a first heat sink having the inner fins on the opposite side and a second heat sink is formed by cutting a rectangular parallelepiped metal plate having high thermal conductivity.

4. The electronic device according to claim 1,
wherein the heat-producing components mounted on the circuit boards are power amplifiers.

5. The electronic device according to claim 1,
wherein the circuit boards are attached to bosses on the first end face plate and the second end face plate respectively.

6. The electronic device according to claim 1,
wherein in the first end face plate and the second end face plate, the circuit board is attached to a substantially entire surface of one of the end face plates, and the circuit board is attached to a part of the other one of the end face plates, and
the area in which the heat-producing components are not mounted is an area to which the circuit board is not attached in the other end face plate.

7. The electronic device according to claim 1,
wherein the electronic device is used as a base station for wireless communication for a wireless terminal, and the inside of the casing is waterproofed to the outside.

8. The electronic device according to claim 1,
wherein the inner fins protrude from a base plate of a third heat sink that is formed separately from the casing,
a recessed portion is formed in a portion in the area in which the circuit board is not mounted in the first end face plate or the second end face plate, and
the base plate of the heat sink is fit and attached into the recessed portion in a state in which the thermal conductivity is ensured such that the inner fins are disposed in the space in the casing.

9. The electronic device according to claim 8,
wherein a thermally conductive member is disposed between the recessed portion and the base plate such that the heat absorbed by the heat sink is conducted to the first end face plate or the second end face plate.
